(19) United States
(12) Patent Application Publication
(10) Pub. No.: US 2025/0104978 A1
(43) Pub. Date: Mar. 27, 2025

(54) RING ASSEMBLY AND SUBSTRATE PROCESSING APPARATUS COMPRISING THE SAME

(71) Applicant: SEMES CO., LTD., Cheonan-si (KR)

(72) Inventors: Dong Mok LEE, Chungcheongnam-do (KR); Chun Loon CHA, Gyeonggi-do (KR); Jong Chan PARK, Seoul (KR); Chae Kyun OH, Seoul (KR); Hyung Joon KIM, Gyeonggi-do (KR)

(73) Assignee: SEMES CO., LTD., Cheonan-si (KR)

(21) Appl. No.: 18/794,502

(22) Filed: Aug. 5, 2024

(30) Foreign Application Priority Data
Sep. 26, 2023 (KR) 10-2023-0128965

(51) Int. Cl. H01J 37/32

(52) U.S. Cl. CPC H01J 37/32642; H01J 2237/334

(57) ABSTRACT

The ring assembly for a substrate processing apparatus, in which a plasma process is performed, of the present invention comprises an inner ring, in which a first plasma region is formed, an outer ring provided outside the inner ring, in which a second plasma region with a lower plasma distribution than the first plasma region is formed, and a cover ring provided on an upper surface of the outer ring, having a thickness smaller than that of the inner ring, and made of a material that has a lower etching reaction to plasma than the outer ring.

This application claims the benefit of Korean Patent Application No. 10-2023-0128965, filed on Sep. 26, 2023, in the Korean Intellectual Property Office, the disclosure of which is incorporated herein by reference in its entirety.

### BACKGROUND

### 1. Field

The present invention relates to a ring assembly for a substrate processing apparatus and a substrate processing apparatus including the same.

### 2. Description of the Related Art

The process of manufacturing a semiconductor comprises a deposition process to form a film on a semiconductor wafer (hereinafter referred to as a substrate), a chemical/mechanical polishing process to flatten the film, a photolithography process to form a photoresist pattern on the film, an etching process to form a film into a pattern with electrical characteristics using a photoresist pattern, an ion implantation process to inject specific ions into a predetermined region of the substrate, a cleaning process to remove impurities on the substrate, and an inspection process to inspect the surface of the substrate on which the film or the pattern is formed.

The etching process is a process for removing exposed regions of the photoresist pattern formed by the photolithography process on the substrate. Types of etching processes can be divided into dry etching and wet etching.

The dry etching process forms an electric field by applying high-frequency power to the upper and lower electrodes installed at a predetermined distance in a sealed internal space where the etching process is performed, and applies an electric field to the reactive gas supplied into the sealed space to activate the reactive gas to create a plasma state. And then, the ions in the plasma etch the substrate located on the lower electrode.

At this time, it is necessary to form plasma uniformly over the entire upper surface of the substrate. A ring assembly is provided to uniformly form plasma over the entire upper surface of the substrate. The ring assembly is installed to surround an edge of the electrostatic chuck disposed on the lower electrode.

An electric field is formed on the upper part of the electrostatic chuck by applying high frequency power, and the ring assembly greatly expands the region where the electric field is formed compared to the region where the substrate is located. Accordingly, the substrate is located at the center of the region where plasma is formed, and thus the substrate can be uniformly etched.

During this process, the ring assembly may be etched. As the ring assembly continues to be etched, the shape of the ring assembly changes. If the shape of the ring assembly changes, the plasma in the ring assembly becomes non-uniform and the plasma is not formed uniformly on the upper part of the substrate, resulting in a decrease in the etching precision of the substrate.

### SUMMARY

The problem to be solved by the present invention is to provide a ring assembly for a substrate processing apparatus that can minimize etching of the ring assembly, thereby preventing the etching precision of the substrate from deteriorating or increasing the replacement cycle of the ring assembly, and substrate processing apparatus including the same.

The objects of the present invention are not limited to the objects mentioned above, and other objects not mentioned will be clearly understood by those skilled in the art from the description below.

One aspect of the ring assembly for a substrate processing apparatus, in which a plasma process is performed, of the present invention to achieve the above object comprises an inner ring, in which a first plasma region is formed, an outer ring provided outside the inner ring, in which a second plasma region with a lower plasma distribution than the first plasma region is formed, and a cover ring provided on an upper surface of the outer ring, having a thickness smaller than that of the inner ring, and made of a material that has a lower etching reaction to plasma than the outer ring.

One aspect of the substrate processing apparatus of the present invention to achieve the above another object comprises a chamber, in which a processing space where a plasma process is performed is formed, a support provided inside the chamber and for supporting a substrate, a ring assembly surrounding a top of the support, and a gas supply unit for supplying process gas into an inside of the chamber, wherein the ring assembly comprises an inner ring, in which a first plasma region is formed, an outer ring provided outside the inner ring, in which a second plasma region with a lower plasma distribution than the first plasma region is formed, and a cover ring provided on an upper surface of the outer ring, having a thickness smaller than that of the inner ring, and made of a material that has a lower etching reaction to plasma than the outer ring.

Another aspect of the substrate processing apparatus of the present invention to achieve the above object comprises a chamber, in which a processing space where a plasma etching process is performed is formed, a support provided inside the chamber and for supporting a substrate, a ring assembly surrounding a top of the support, and a gas supply unit for supplying process gas into an inside of the chamber, wherein the ring assembly comprises an inner ring made of silicon, in which a first plasma region is formed, an outer ring provided outside the inner ring and made of quartz material, in which a second plasma region with a lower plasma distribution than the first plasma region is formed, and a cover ring provided on an upper surface of the outer ring, not integrally formed with the inner ring but separated from the inner ring, having a thickness smaller than that of the inner ring, and made of a material that has a lower etching reaction to plasma than the outer ring, wherein a top of the outer ring has a flat surface and an inclined surface sloping downward from an edge of the flat surface in an outward direction, wherein the cover ring has a thickness of 0.1 mm to 7 mm, is provided as a ring-shaped plate containing at least one material of silicon (Si), silicon carbide (SiC), or yttrium oxide (Y₂O₃), and covers the flat surface.

Specific details of other embodiments are included in the detailed description and drawings.

### BRIEF DESCRIPTION OF THE DRAWINGS

These and/or other aspects will become apparent and more readily appreciated from the following description of the embodiments, taken in conjunction with the accompanying drawings in which:

FIG. 1 is a diagram illustrating a substrate processing apparatus according to a first embodiment of the present invention;

FIG. 2 is a diagram illustrating region A of FIG. 1;

FIG. 3 is a cross-sectional view showing the outer ring of the substrate processing apparatus according to the first embodiment of the present invention;

FIG. 4 is a diagram illustrating a ring assembly of a substrate processing apparatus according to a second embodiment of the present invention; and

FIG. 5 is a diagram showing a state before and after etching of the ring assembly for a substrate processing apparatus of a comparative example.

### DETAILED DESCRIPTION

Hereinafter, preferred embodiments of the present invention will be described in detail with reference to the attached drawings. The advantages and features of the present invention and methods for achieving them will become clear by referring to the embodiments described in detail below along with the accompanying drawings. However, the present invention is not limited to the embodiments disclosed below and may be implemented in various different forms. The present embodiments are merely intended to ensure that the disclosure of the present invention is complete, and provided to fully inform those skilled in the art on the scope of the invention, and the present invention is only defined by the scope of the claims. Like reference numerals refer to like elements throughout the specification.

The terminology used herein is for describing embodiments and is not intended to limit the invention. As used herein, singular forms also include plural forms, unless specifically stated otherwise in the context. As used herein, “comprises” and/or “comprising” does not rule out the addition or the presence of one or more other components, steps, operations and/or elements.

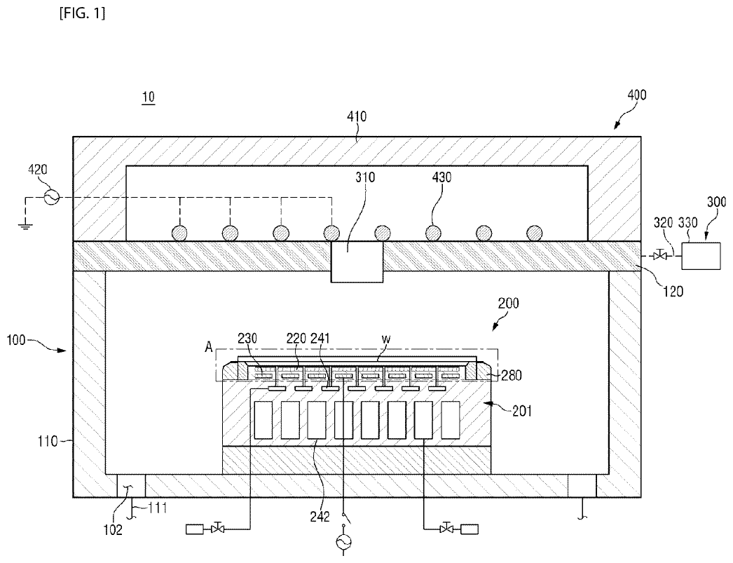

FIG. 1 is a diagram illustrating a substrate processing apparatus according to a first embodiment of the present invention.

Referring to FIG. 1, the substrate processing apparatus 10 according to the first embodiment of the present invention may comprise a chamber 100, a substrate support device 200, a gas supply unit 300, and a plasma generation unit 400. In addition, the substrate processing apparatus 10 of this embodiment can perform an etching process using plasma, and both CCP (Capacitively Coupled Plasma) type and ICP (Inductively Coupled Plasma) type can be applied. That is, the substrate processing apparatus 10 will be described below by using ICP as an example, but it is not limited thereto and various modifications are possible, such as CCP type can be applied.

The chamber 100 may provide a processing space where a processing process for the substrate W is performed. The processing process is a process using plasma, and may be, for example, an etching process. The chamber 100 may be provided in a sealed structure to maintain a vacuum. The chamber 100 may have a hollow cube, a hollow cylinder, or other shapes. By way of example, the chamber 100 may include a body 110 and a window module 120.

A space with an open top may be formed in the body 110. The space of the body 110 may be provided as a processing space where a substrate W processing process is performed. The body 110 may be made of a metal material (e.g., aluminum). An exhaust hole 102 may be formed on the bottom surface of the body 110. The exhaust hole 102 may be connected to the exhaust line 111. Reaction by-products generated during the process may be discharged to the outside through the exhaust line 111.

The window module 120 may be provided at the upper part of the processing space and cover the open upper surface of the body 110, thereby sealing the space of the body 110. The window module 120 may be made of a different material from the body 110.

For example, the window module 120 may transmit high frequency (radio-frequency) and may be provided as a dielectric substance. The temperature of the window module 120 increases as process time and power increase, and cooling may be required for temperature control. The window module 120 may allow fluid with a temperature lower than that of the processing space to pass through the window module 120 for cooling purposes. The window module 120 may be provided with a flow path (not shown) that forms a fluid movement path for direct cooling.

Additionally, the window module 120 may have a gas supply nozzle 310 formed at the center for discharging gas. The gas supply nozzle 310 may be in communication with the block 350, so that process gas may be discharged. A spray hole may be formed on the bottom surface of the gas supply nozzle 310. The spray hole may supply process gas to the inside of the chamber 100.

The substrate support device 200 is located inside the body 110 and may support the substrate W. The substrate support device 200 may be an electrostatic chuck that adsorbs the substrate W using electrostatic force, but is not limited thereto. In contrast, the substrate support device 200 is capable of various modifications such that it can support the substrate W in various ways, such as mechanical clamping. Hereinafter, adsorption of the substrate W using electrostatic force will be exemplified.

The substrate support device 200 may include a support 201 and a ring assembly 280.

The support 201 may support the substrate W. The support 201 may be made of a disc-shaped dielectric substance and aluminum. A lower electrode 220 and a heater 230 may be embedded in the support 201. An electric force may be applied between the lower electrode 220 and the substrate W due to the current applied to the lower electrode 220, and the substrate W may be adsorbed to the support 201 by the electric force. The heater 230 may generate heat by resisting a current applied from an external power source. The generated heat may be transferred to the substrate W through the support 201. The substrate W may be maintained at a predetermined temperature by the heat generated by the heater 230.

A first circulation passage 241 and a second circulation passage 242 may be provided in the support 201. As an example, the first circulation passage 241 may be provided as a passage through which a heat transfer medium such as helium gas moves. The heat transfer medium may be supplied to the bottom surface of the substrate W. The second circulation passage 242 may be provided as a passage through which a temperature control fluid (e.g., coolant) moves, and the temperature of the support 201 may be adjusted by the temperature control fluid.

Additionally, the ion particles contained in the plasma may be attracted by the electric force formed in the substrate support device 200 and move to the substrate support device 200, and may collide with the substrate W during the movement to perform an etching process.

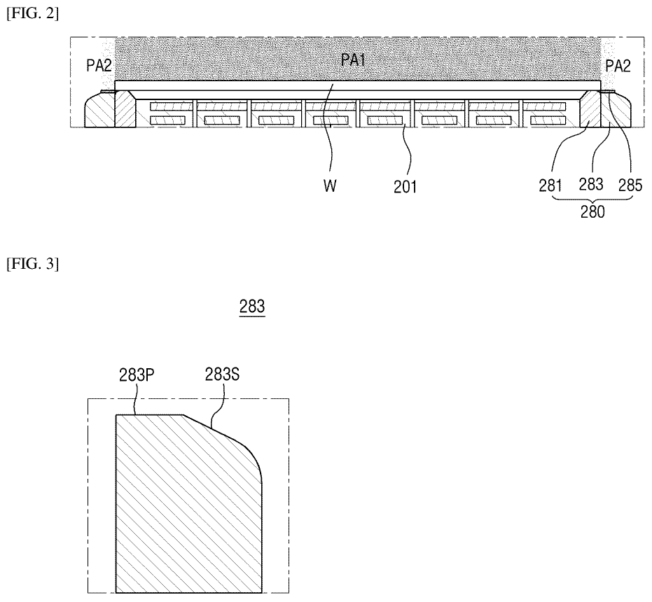

The ring assembly 280 can improve the etching precision of the substrate W by focusing plasma on the substrate W. The ring assembly 280 may be installed on the support 201 and may be arranged to surround the substrate W. The ring assembly 280 may have a structure in which multiple rings are combined. The ring assembly 280 will be described with reference to FIGS. 2 and 3.

The gas supply unit 300 may supply process gas to the inside of the chamber 100. The gas supply unit 300 may include a gas supply line 320 and a gas storage unit 330. The gas supply line 320 may supply the process gas stored in the gas storage unit 330 to the gas supply nozzle 310.

The plasma generation unit 400 may apply high frequency power to the inside of the chamber 100 to excite the process gas supplied inside the chamber 100. The plasma generation unit 400 may include a housing 410, an upper power source 420, and an antenna 430.

The housing 410 may be located on top of the window module 120, and a space may be formed therein. The inside of the housing 410 may be provided as a space where the antenna 430 is located. The upper power source 420 may generate high frequency current. The generated high frequency current may be applied to the antenna 430.

The antenna 430 may be provided above the window module 120, and power may be applied to apply high frequency power to the inside of the chamber 100. High frequency power applied from the antenna 430 may excite the process gas remaining inside the chamber 100. The excited process gas may be provided to the substrate W to process the substrate W. The excited process gas can perform an etching process.

Hereinafter, the ring assembly 280 will be described with reference to the drawings.

FIG. 2 is a view showing region A of FIG. 1, and FIG. 3 is a cross-sectional view showing the outer ring of the substrate processing apparatus according to the first embodiment of the present invention. And FIG. 5 is a diagram showing a state before and after etching of the ring assembly for a substrate processing apparatus of a comparative example.

The ring assembly 280 of the first embodiment may include an inner ring 281, an outer ring 283, and a cover ring 285.

The inner ring 281 may be made of a silicon material, and a first plasma region PA1 having the same or similar plasma distribution (density) as that of the upper part of the substrate W may be formed. That is, a first plasma region PA1 that has a higher plasma distribution than that of the outer ring 283 may be formed in the substrate W and the inner ring 281. For example, different plasma density of the first plasma region PA1 and the second plasma region PA2 could be formed differently depending on the material/thickness/shape of the inner ring 281 and the outer ring 283 and/or the influence of the electrode.

The first plasma region PA1 of the inner ring 281 has a higher plasma distribution than the second plasma region PA2, so the plasma may be focused around the substrate W. That is, the plasma distribution formed in the inner ring 281 and the outer ring 283 are different, and the inner ring 281 has a higher plasma distribution than the outer ring 283, so the plasma is focused on the substrate W, and the plasma etching process of the substrate W can be performed precisely.

The outer ring 283 may surround the inner ring 281 on the outside of the inner ring 281. The outer ring 283 may be made of quartz material, and the second plasma region PA2 may be formed. The second plasma region PA2 may have a lower plasma distribution than the first plasma region PA1.

And the top of the outer ring 283 may have a flat surface 283P and an inclined surface 283S (see FIG. 3). The second plasma region PA2 may be formed at the top of the outer ring 283, and the influence of the electrode may be small on the inclined surface 283S, so that the plasma distribution may be lower on the inclined surface 283S compared to the flat surface 283P.

Here, the flat surface 283P is an inner region of the outer ring 283 and is adjacent to the inner ring 281 and may form a flat surface. The flat surface 283P may be made of the same material as the inclined surface 283S, but the influence of the electrode may be greater than that of the inclined surface 283S, and it has no change in height unlike the inclined surface 283S, so that the plasma distribution may be higher than that of the inclined surface 283S. Here, the reason why the influence of the electrode on the inclined surface 283S is greater than on the flat surface 283P is because the influence of the electrode on the wall inside the chamber 100 is reduced. That is, this is because the radius of the electrode is smaller than the radius of the chamber 100.

The inclined surface 283S may slope downward in an outward direction from the edge of the flat surface 283P. The inclined surface 283S is located outside the flat surface 283P, so that it can be arranged at a position furthest from the substrate W in the ring assembly 280, and the influence of the electrode can be minimal. The plasma distribution of the inclined surface 283S may be lower than that of the flat surface 283P.

In addition, reaction by-products (e.g., polymers) generated during the etching process may move outward from the center of the substrate W and be discharged to the outside through the exhaust hole 102 and the exhaust line 111. The reaction by-products may pass through the upper part of the ring assembly 280. At this time, if the upper surface of the outer ring 283 does not have an inclined surface but is all flat surface or protrudes, reaction by-products may hit the corners of the ring assembly 280 and accumulate. Reaction by-products accumulated in the ring assembly 280 may reflow into the substrate W and act as particles during repeated processes.

However, in this embodiment, the corners of the edge of the ring assembly 280 have a cut shape, that is, the outer ring 283 includes an inclined surface 283S, thereby reducing the problem of reaction by-products being loaded on the ring assembly 280.

And the outer ring 283 is made of a different material from the inner ring 281 and is provided to focus the plasma on the substrate W. In the outer ring 283, as shown in FIG. 5 of the comparative example, etching is performed on the flat surface 283p, and the etching rate can be high due to lower plasma resistance (etch resistance) compared to the inner ring 281.

That is, the outer ring 283 has a shorter replacement cycle than the inner ring 281 because its shape is changed by etching when the substrate processing process is repeated. However, in this embodiment, the outer ring 283 is covered with the cover ring 285, so that etching can be minimized. Here, the solid line in FIG. 5 shows the state before the ring assembly 280 is etched, and the dotted line shows the state in which the ring assembly 280 is etched after the process is repeated.

The cover ring 285 may cover the outer ring 283 in order to extend the replacement cycle of the outer ring 283. The cover ring 285 may not be formed integrally with the inner ring 281 but may be separated from the inner ring 281 to minimize or prevent the high plasma density of the inner ring 281 (density of the first plasma region PA1) from extending from the inner ring 281 toward the outer ring 283.

That is, the cover ring 285 is not connected to the inner ring 281, and the first plasma region PA1 is formed in the inner ring 281, and the cover ring 285 can cover only the outer ring 283 so that the influence of the inner ring 281 is cut off on the outer ring 283.

In addition, the cover ring 285 may be formed to have a thickness smaller than that of the inner ring 281 on the upper surface of the outer ring 283. For example, the cover ring 285 may be provided as a ring-shaped plate with a thickness of 0.1 mm to 7 mm. The cover ring 285 provided as a plate can be coupled to the outer ring 283 by resin bonding. For example, resin bonding may be formed on the bottom surface, side surface, or both bottom and side surfaces of the cover ring 285. However, it is not limited to this, and various modifications are possible, such as the cover ring 285 being provided in a coating manner.

Additionally, the cover ring 285 may be made of a material with a lower etching reaction to plasma (a material with excellent etching resistance) than the outer ring 283. For example, the cover ring 285 may be made of at least one material of silicon (Si), silicon carbide (SiC), and yttrium oxide (Y₂O₃). However, it is not limited to this. The cover ring 285 may be made of a ceramic material.

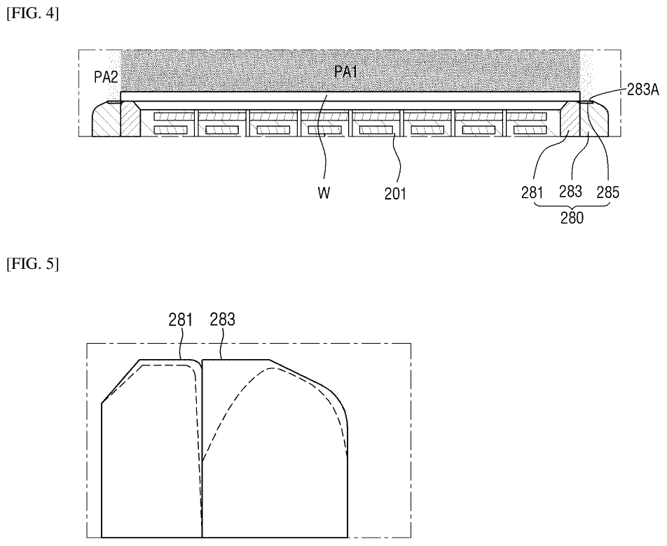

Hereinafter, a modified example of this embodiment will be described with reference to FIG. 4, and overlapping descriptions of the same configuration performing the same function will be omitted.

FIG. 4 is a diagram illustrating a ring assembly of a substrate processing apparatus according to a second embodiment of the present invention. With reference to FIG. 4, differences from those described using FIGS. 1 to 3 will be mainly explained.

Referring to FIG. 4, the substrate processing apparatus 10 of the second embodiment may comprise a chamber 100, a substrate support device 200, and a gas supply unit 300 the same as or similar to the substrate processing apparatus 10 of the first embodiment. And it may include a plasma generation unit 400.

The ring assembly 280 of the second embodiment may comprise an inner ring 281, an outer ring 283, and a cover ring 285 the same as or similar to the first embodiment.

Meanwhile, the ring assembly 280 of the second embodiment differs in that a step 283A is formed on the flat surface 283P of the outer ring 283, and a cover ring 285 is provided at the step 283A. That is, the flat surface 283P of the outer ring 283 has a concave structure corresponding to the thickness of the cover ring 285, so that the cover ring 285 can be seated.

In the substrate processing apparatus 10 according to this embodiment, the outer ring 283 is covered with a cover ring 285 having excellent etch resistance, so that the replacement cycle of the ring assembly 280 is increased or deterioration in etching precision of the substrate W due to shape deformation of the ring assembly 280 can be minimized.

Although the embodiments of the present invention have been described with reference to the above and accompanying drawings, those skilled in the art to which the present invention pertains can understand that the present invention can be practiced in other specific forms without changing the technical spirit or essential features. Therefore, the embodiments described above should be understood as illustrative in all respects and not limiting.

[Reference Numeral]

| | |
|---|---|
| 10: substrate processing apparatus | 100: chamber |
| 200: substrate support device | 280: ring assembly |
| 281: inner ring | 283: outer ring |
| 285: cover ring | 300: gas supply unit |

What is claimed is:

1. A ring assembly for a substrate processing apparatus, in which a plasma process is performed, comprising:
an inner ring, in which a first plasma region is formed;
an outer ring provided outside the inner ring, in which a second plasma region with a lower plasma distribution than the first plasma region is formed; and
a cover ring provided on an upper surface of the outer ring, having a thickness smaller than that of the inner ring, and made of a material that has a lower etching reaction to plasma than the outer ring.

2. The ring assembly of claim 1, wherein the covering ring is not formed integrally with the inner ring but separated from the inner ring.

3. The ring assembly of claim 1, wherein a top of the outer ring comprises,
a flat surface; and
an inclined surface sloping downward from an edge of the flat surface in an outward direction.

4. The ring assembly of claim 3, wherein the cover ring covers the flat surface excluding the inclined surface of the outer ring.

5. The ring assembly of claim 1, wherein the cover ring has a thickness of 0.1 mm to 7 mm.

6. The ring assembly of claim 1, wherein the cover ring is provided as a ring-shaped plate.

7. The ring assembly of claim 1, wherein the cover ring is provided as a coating on an upper surface of the outer ring.

8. The ring assembly of claim 1, wherein the inner ring includes a silicone material,
wherein the outer ring includes a quartz material.

9. The ring assembly of claim 8, wherein the cover ring comprises at least one material of silicon (Si), silicon carbide (SiC), and yttrium oxide (Y₂O₃).

10. The ring assembly of claim 8, wherein the cover ring is made of a ceramic material.

11. An apparatus for processing a substrate comprising:
a chamber, in which a processing space where a plasma process is performed is formed;
a support provided inside the chamber and for supporting a substrate;
a ring assembly surrounding a top of the support; and
a gas supply unit for supplying process gas into an inside of the chamber,
wherein the ring assembly comprises,
an inner ring, in which a first plasma region is formed;
an outer ring provided outside the inner ring, in which a second plasma region with a lower plasma distribution than the first plasma region is formed; and
a cover ring provided on an upper surface of the outer ring, having a thickness smaller than that of the inner ring, and made of a material that has a lower etching reaction to plasma than the outer ring.

12. The apparatus of claim 11, wherein the covering ring is not formed integrally with the inner ring but separated from the inner ring.

13. The apparatus of claim 11, wherein a top of the outer ring comprises,
a flat surface; and
an inclined surface sloping downward from an edge of the flat surface in an outward direction.

14. The apparatus of claim 13, wherein the cover ring covers the flat surface excluding the inclined surface of the outer ring.

15. The apparatus of claim 14, wherein the outer ring has a step where the cover ring is seated.

16. The apparatus of claim 11, wherein the inner ring includes a silicone material, wherein the outer ring includes a quartz material.

17. The ring assembly of claim 16, wherein the cover ring has a thickness of 0.1 mm to 7 mm,
wherein the cover ring comprises at least one material of silicon (Si), silicon carbide (SiC), and yttrium oxide (Y₂O₃).

18. An apparatus for processing a substrate comprising:
a chamber, in which a processing space where a plasma etching process is performed is formed;
a support provided inside the chamber and for supporting a substrate;
a ring assembly surrounding a top of the support; and
a gas supply unit for supplying process gas into an inside of the chamber,
wherein the ring assembly comprises,
an inner ring made of silicon, in which a first plasma region is formed;
an outer ring provided outside the inner ring and made of quartz material, in which a second plasma region with a lower plasma distribution than the first plasma region is formed; and
a cover ring provided on an upper surface of the outer ring, not integrally formed with the inner ring but separated from the inner ring, having a thickness smaller than that of the inner ring, and made of a material that has a lower etching reaction to plasma than the outer ring,
wherein a top of the outer ring has a flat surface and an inclined surface sloping downward from an edge of the flat surface in an outward direction,
wherein the cover ring has a thickness of 0.1 mm to 7 mm, is provided as a ring-shaped plate containing at least one material of silicon (Si), silicon carbide (SIC), or yttrium oxide (Y₂O₃), and covers the flat surface.
